(19) United States
(12) Patent Application Publication
(10) Pub. No.: US 2025/0035470 A1
(43) Pub. Date: Jan. 30, 2025

(54) ELECTRONIC DEVICE INCLUDING GRIP SENSOR AND METHOD

(71) Applicant: Samsung Electronics Co., Ltd., Suwon-si (KR)

(72) Inventors: Jongwon LEE, Suwon-si (KR); Janghoon HAN, Suwon-si (KR); Heejun KWON, Suwon-si (KR); Seohyeon PARK, Suwon-si (KR); Daehee PARK, Suwon-si (KR)

(21) Appl. No.: 18/913,239

(22) Filed: Oct. 11, 2024

Related U.S. Application Data
(63) Continuation of application No. PCT/KR2023/002984, filed on Mar. 3, 2023.

(30) Foreign Application Priority Data
May 6, 2022 (KR) 10-2022-0055950
Jul. 14, 2022 (KR) 10-2022-0087211

(51) Int. Cl. G01D 5/24; H04M 1/72454

(52) U.S. Cl. CPC G01D 5/24; H04M 1/72454; H04M 2250/12

(57) ABSTRACT

An electronic device is provided. The electronic device includes a grip sensor, memory storing one or more computer programs, one or more processors communicatively coupled to the grip sensor and the memory, wherein the one or more computer programs include computer-executable instructions that, when executed by the one or more processors individually or collectively, cause the electronic device to adjust a capacitance of a capacitor in the grip sensor to change a voltage outputted from the grip sensor, based on a first capacitance stored in the memory, after the capacitance of the capacitor is adjusted to a second capacitance greater than the first capacitance, detect a grip on the electronic device using the voltage changed by the capacitor, based on identifying that the capacitance of the capacitor is decreased to a third capacitance smaller than the first capacitance, change the first capacitance stored in the memory to the third capacitance, and based on a number of the capacitance of the capacitor adjusted smaller than the second capacitance, change the first capacitance stored in the memory to the second capacitance.

### CROSS-REFERENCE TO RELATED APPLICATION(S)

This application is a continuation application, claiming priority under § 365(c), of an International application No. PCT/KR2023/002984, filed on Mar. 3, 2023, which is based on and claims the benefit of a Korean patent application number 10-2022-0055950, filed on May 6, 2022, in the Korean Intellectual Property Office, and of a Korean patent application number 10-2022-0087211, filed on Jul. 14, 2022, in the Korean Intellectual Property Office, the disclosure of each of which is incorporated by reference herein in its entirety.

### BACKGROUND

### 1. Field

The disclosure relates to an electronic device including a grip sensor and a method.

### 2. Description of Related Art

A grip sensor of an electronic device may detect a grip on the electronic device. The electronic device may detect a grip on the electronic device based on a capacitance of a capacitor included in the grip sensor and a voltage outputted from the grip sensor. For example, the electronic device may detect a grip on the electronic device based on a capacitance caused based on the approach of an external object and the voltage outputted from the grip sensor.

The above information is presented as background information only to assist with an understanding of the disclosure. No determination has been made, and no assertion is made, as to whether any of the above might be applicable as prior art with regard to the disclosure.

### SUMMARY

Aspects of the disclosure are to address at least the above-mentioned problems and/or disadvantages and to provide at least the advantages described below. Accordingly, an aspect of the disclosure is to provide an electronic device including a grip sensor and a method.

Additional aspects will be set forth in part in the description which follows and, in part, will be apparent from the description, or may be learned by practice of the presented embodiments.

In accordance with an aspect of the disclosure, an electronic device is provided. The electronic device includes a grip sensor, memory storing one or more computer programs, and one or more processors communicatively coupled to the grip sensor and the memory, wherein the one or more computer programs include computer-executable instructions that, when executed by the one or more processors individually or collectively, cause the electronic device to adjust a capacitance of a capacitor in the grip sensor to change a voltage outputted from the grip sensor, based on a first capacitance stored in the memory, after the capacitance of the capacitor is adjusted to a second capacitance greater than the first capacitance, detect a grip on the electronic device using the voltage changed by the capacitor, based on identifying that the capacitance of the capacitor is decreased to a third capacitance smaller than the first capacitance, change the first capacitance stored in the memory to the third capacitance, and based on a number of the capacitance of the capacitor adjusted smaller than the second capacitance, change the first capacitance stored in the memory to the second capacitance.

In accordance with another aspect of the disclosure, an electronic device is provided. The electronic device includes a grip sensor, memory storing one or more computer programs, one or more processors communicatively coupled to the grip sensor and the memory, wherein the one or more computer programs include computer-executable instructions that, when executed by the one or more processors individually or collectively, cause the electronic device to adjust a capacitance of a capacitor in the grip sensor, in a range indicated by a first capacitance stored in the memory, based on whether a voltage outputted from the grip sensor maintains a preset voltage by a second capacitance in the range, detect a grip on the electronic device independently from the first capacitance, while the capacitance of the capacitor is adjusted based on occurrence of a preset event, detect a grip on the electronic device based on the first capacitance and the voltage.

In accordance with another aspect of the disclosure, a method of operating an electronic device is provided. The method includes adjusting a capacitance of a capacitor in a grip sensor to change a voltage outputted from the grip sensor, based on a first capacitance stored in memory, after the capacitance of the capacitor is adjusted to a second capacitance greater than the first capacitance, detecting a grip on the electronic device using the voltage changed by the capacitor, based on identifying that the capacitance of the capacitor is decreased to a third capacitance smaller than the first capacitance, changing the first capacitance stored in the memory to the third capacitance, and, based on a number of the capacitance of the capacitor adjusted smaller than the second capacitance, changing the first capacitance stored in the memory to the second capacitance.

In accordance with another aspect of the disclosure, an electronic device is provided. The electronic device includes a grip sensor, memory storing one or more computer programs, and one or more processors communicatively coupled to the grip sensor and the memory, wherein the one or more computer programs include computer-executable instructions that, when executed by the one or more processors individually or collectively, cause the electronic device to adjust a capacitance of a capacitor in the grip sensor, in a range indicated by a first capacitance stored in the memory, based on whether a voltage outputted from the grip sensor maintains a preset voltage by a second capacitance in the range, detect a grip on the electronic device independently from the first capacitance, and, while the capacitance of the capacitor is adjusted based on occurrence of a preset event, detect a grip on the electronic device based on the first capacitance and the voltage.

In accordance with another aspect of the disclosure, one or more non-transitory computer-readable storage media storing computer-executable instructions that, when executed by one or more processors individually or collectively, cause an electronic device to perform operations are provided. The operations include adjusting a capacitance of a capacitor in a grip sensor to change a voltage outputted from the grip sensor, based on a first capacitance stored in memory, after the capacitance of the capacitor is adjusted to a second capacitance greater than the first capacitance, detecting a grip on the electronic device using the voltage changed by the capacitance, based on identifying that the capacitance of the capacitor is decreased to a third capacitance smaller than the first capacitance, changing the first capacitance stored in the memory to the third capacitance, and based on a number of the capacitance of the capacitor adjusted smaller than the second capacitance, changing the first capacitance stored in the memory to the second capacitance.

Other aspects, advantages, and salient features of the disclosure will become apparent to those skilled in the art from the following detailed description, which, taken in conjunction with the annexed drawings, discloses various embodiments of the disclosure.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a block diagram of an electronic device in a network environment according to an embodiment of the disclosure;

FIG. 2 is a diagram for describing an operation of an electronic device detecting a grip on the electronic device using a grip sensor, according to an embodiment of the disclosure;

FIG. 3 illustrates a simplified block diagram of an electronic device according to an embodiment of the disclosure;

FIG. 4 illustrates at least a portion of a circuit included in a grip sensor of an electronic device according to an embodiment of the disclosure;

FIG. 5 illustrates a flowchart regarding an operation of an electronic device according to an embodiment of the disclosure;

FIG. 6 illustrates a flowchart regarding an operation of an electronic device according to an embodiment of the disclosure;

FIG. 7 illustrates a range indicated by a capacitance of a first capacitor and a capacitance stored in memory or a controller, according to an embodiment of the disclosure; and

FIG. 8 illustrates a flowchart regarding an operation of an electronic device according to an embodiment of the disclosure.

Throughout the drawings, it should be noted that like reference numbers are used to depict the same or similar elements, features, and structures.

### DETAILED DESCRIPTION

The following description with reference to the accompanying drawings is provided to assist in a comprehensive understanding of various embodiments of the disclosure as defined by the claims and their equivalents. It includes various specific details to assist in that understanding but these are to be regarded as merely exemplary. Accordingly, those of ordinary skill in the art will recognize that various changes and modifications of the various embodiments described herein can be made without departing from the scope of the disclosure. In addition, descriptions of well-known functions and constructions may be omitted for clarity and conciseness.

The terms and words used in the following description and claims are not limited to the bibliographical meanings, but, are merely used by the inventor to enable a clear and consistent understanding of the disclosure. Accordingly, it should be apparent to those skilled in the art that the following description of various embodiments of the disclosure is provided for illustration purpose only and not for the purpose of limiting the disclosure as defined by the appended claims and their equivalents.

It is to be understood that the singular forms “a,” “an,” and “the” include plural referents unless the context clearly dictates otherwise. Thus, for example, reference to “a component surface” includes reference to one or more of such surfaces.

It should be appreciated that the blocks in each flowchart and combinations of the flowcharts may be performed by one or more computer programs which include computer-executable instructions. The entirety of the one or more computer programs may be stored in a single memory device or the one or more computer programs may be divided with different portions stored in different multiple memory devices.

Any of the functions or operations described herein can be processed by one processor or a combination of processors. The one processor or the combination of processors is circuitry performing processing and includes circuitry like an application processor (AP, e.g., a central processing unit (CPU)), a communication processor (CP, e.g., a modem), a graphical processing unit (GPU), a neural processing unit (NPU) (e.g., an artificial intelligence (AI) chip), a wireless-fidelity (Wi-Fi) chip, a Bluetooth™ chip, a global positioning system (GPS) chip, a near field communication (NFC) chip, connectivity chips, a sensor controller, a touch controller, a finger-print sensor controller, a display drive integrated circuit (IC), an audio CODEC chip, a universal serial bus (USB) controller, a camera controller, an image processing IC, a microprocessor unit (MPU), a system on chip (SoC), an IC, or the like.

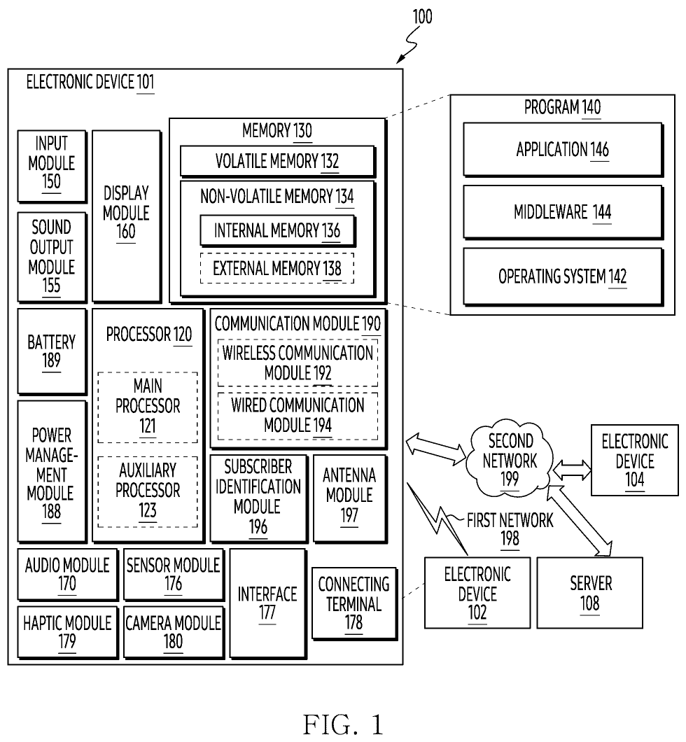

FIG. 1 is a block diagram illustrating an electronic device in a network environment according to an embodiment of the disclosure.

Referring to FIG. 1, an electronic device 101 in a network environment 100 may communicate with an external electronic device 102 via a first network 198 (e.g., a short-range wireless communication network), or at least one of an external electronic device 104 or a server 108 via a second network 199 (e.g., a long-range wireless communication network). According to an embodiment of the disclosure, the electronic device 101 may communicate with the external electronic device 104 via the server 108. According to an embodiment of the disclosure, the electronic device 101 may include a processor 120, memory 130, an input module 150, a sound output module 155, a display module 160, an audio module 170, a sensor module 176, an interface 177, a connecting terminal 178, a haptic module 179, a camera module 180, a power management module 188, a battery 189, a communication module 190, a subscriber identification module (SIM) 196, or an antenna module 197. In some embodiments of the disclosure, at least one of the components (e.g., the connecting terminal 178) may be omitted from the electronic device 101, or one or more other components may be added in the electronic device 101. In some embodiments of the disclosure, some of the components (e.g., the sensor module 176, the camera module 180, or the antenna module 197) may be implemented as a single component (e.g., the display module 160).

The processor 120 may execute, for example, software (e.g., a program 140) to control at least one other component (e.g., a hardware or software component) of the electronic device 101 coupled with the processor 120, and may perform various data processing or computation. According to an embodiment of the disclosure, as at least part of the data processing or computation, the processor 120 may store a command or data received from another component (e.g., the sensor module 176 or the communication module 190) in volatile memory 132, process the command or the data stored in the volatile memory 132, and store resulting data in non-volatile memory 134. According to an embodiment of the disclosure, the processor 120 may include a main processor 121 (e.g., a central processing unit (CPU) or an application processor (AP)), or an auxiliary processor 123 (e.g., a graphics processing unit (GPU), a neural processing unit (NPU), an image signal processor (ISP), a sensor hub processor, or a communication processor (CP)) that is operable independently from, or in conjunction with, the main processor 121. For example, when the electronic device 101 includes the main processor 121 and the auxiliary processor 123, the auxiliary processor 123 may be adapted to consume less power than the main processor 121, or to be specific to a specified function. The auxiliary processor 123 may be implemented as separate from, or as part of the main processor 121.

The auxiliary processor 123 may control at least some of functions or states related to at least one component (e.g., the display module 160, the sensor module 176, or the communication module 190) among the components of the electronic device 101, instead of the main processor 121 while the main processor 121 is in an inactive (e.g., a sleep) state, or together with the main processor 121 while the main processor 121 is in an active state (e.g., executing an application). According to an embodiment of the disclosure, the auxiliary processor 123 (e.g., an image signal processor or a communication processor) may be implemented as part of another component (e.g., the camera module 180 or the communication module 190) functionally related to the auxiliary processor 123. According to an embodiment of the disclosure, the auxiliary processor 123 (e.g., the neural processing unit) may include a hardware structure specified for artificial intelligence model processing. An artificial intelligence model may be generated by machine learning. Such learning may be performed, e.g., by the electronic device 101 where the artificial intelligence is performed or via a separate server (e.g., the server 108). Learning algorithms may include, but are not limited to, e.g., supervised learning, unsupervised learning, semi-supervised learning, or reinforcement learning. The artificial intelligence model may include a plurality of artificial neural network layers. The artificial neural network may be a deep neural network (DNN), a convolutional neural network (CNN), a recurrent neural network (RNN), a restricted boltzmann machine (RBM), a deep belief network (DBN), a bidirectional recurrent deep neural network (BRDNN), deep Q-network or a combination of two or more thereof but is not limited thereto. The artificial intelligence model may, additionally or alternatively, include a software structure other than the hardware structure.

The memory 130 may store various data used by at least one component (e.g., the processor 120 or the sensor module 176) of the electronic device 101. The various data may include, for example, software (e.g., the program 140) and input data or output data for a command related thereto. The memory 130 may include the volatile memory 132 or the non-volatile memory 134.

The program 140 may be stored in the memory 130 as software, and may include, for example, an operating system (OS) 142, middleware 144, or an application 146.

The input module 150 may receive a command or data to be used by another component (e.g., the processor 120) of the electronic device 101, from the outside (e.g., a user) of the electronic device 101. The input module 150 may include, for example, a microphone, a mouse, a keyboard, a key (e.g., a button), or a digital pen (e.g., a stylus pen).

The sound output module 155 may output sound signals to the outside of the electronic device 101. The sound output module 155 may include, for example, a speaker or a receiver. The speaker may be used for general purposes, such as playing multimedia or playing record. The receiver may be used for receiving incoming calls. According to an embodiment of the disclosure, the receiver may be implemented as separate from, or as part of the speaker.

The display module 160 may visually provide information to the outside (e.g., a user) of the electronic device 101. The display module 160 may include, for example, a display, a hologram device, or a projector and control circuitry to control a corresponding one of the display, hologram device, and projector. According to an embodiment of the disclosure, the display module 160 may include a touch sensor adapted to detect a touch, or a pressure sensor adapted to measure the intensity of force incurred by the touch.

The audio module 170 may convert a sound into an electrical signal and vice versa. According to an embodiment of the disclosure, the audio module 170 may obtain the sound via the input module 150, or output the sound via the sound output module 155 or a headphone of an external electronic device (e.g., the external electronic device 102) directly (e.g., wiredly) or wirelessly coupled with the electronic device 101.

The sensor module 176 may detect an operational state (e.g., power or temperature) of the electronic device 101 or an environmental state (e.g., a state of a user) external to the electronic device 101, and then generate an electrical signal or data value corresponding to the detected state. According to an embodiment of the disclosure, the sensor module 176 may include, for example, a gesture sensor, a gyro sensor, an atmospheric pressure sensor, a magnetic sensor, an acceleration sensor, a grip sensor, a proximity sensor, a color sensor, an infrared (IR) sensor, a biometric sensor, a temperature sensor, a humidity sensor, or an illuminance sensor.

The interface 177 may support one or more specified protocols to be used for the electronic device 101 to be coupled with the external electronic device (e.g., the external electronic device 102) directly (e.g., wiredly) or wirelessly. According to an embodiment of the disclosure, the interface 177 may include, for example, a high definition multimedia interface (HDMI), a universal serial bus (USB) interface, a secure digital (SD) card interface, or an audio interface.

A connecting terminal 178 may include a connector via which the electronic device 101 may be physically connected with the external electronic device (e.g., the external electronic device 102). According to an embodiment of the disclosure, the connecting terminal 178 may include, for example, an HDMI connector, a USB connector, an SD card connector, or an audio connector (e.g., a headphone connector).

The haptic module 179 may convert an electrical signal into a mechanical stimulus (e.g., a vibration or a movement) or electrical stimulus which may be recognized by a user via his tactile sensation or kinesthetic sensation. According to an embodiment of the disclosure, the haptic module 179 may include, for example, a motor, a piezoelectric element, or an electric stimulator.

The camera module 180 may capture a still image or moving images. According to an embodiment of the disclosure, the camera module 180 may include one or more lenses, image sensors, image signal processors, or flashes.

The power management module 188 may manage power supplied to the electronic device 101. According to an embodiment of the disclosure, the power management module 188 may be implemented as at least part of, for example, a power management integrated circuit (PMIC).

The battery 189 may supply power to at least one component of the electronic device 101. According to an embodiment of the disclosure, the battery 189 may include, for example, a primary cell which is not rechargeable, a secondary cell which is rechargeable, or a fuel cell.

The communication module 190 may support establishing a direct (e.g., wired) communication channel or a wireless communication channel between the electronic device 101 and the external electronic device (e.g., the external electronic device 102, the external electronic device 104, or the server 108) and performing communication via the established communication channel. The communication module 190 may include one or more communication processors that are operable independently from the processor 120 (e.g., the application processor (AP)) and supports a direct (e.g., wired) communication or a wireless communication. According to an embodiment of the disclosure, the communication module 190 may include a wireless communication module 192 (e.g., a cellular communication module, a short-range wireless communication module, or a global navigation satellite system (GNSS) communication module) or a wired communication module 194 (e.g., a local area network (LAN) communication module or a power line communication (PLC) module). A corresponding one of these communication modules may communicate with the external electronic device via the first network 198 (e.g., a short-range communication network, such as Bluetooth™, wireless-fidelity (Wi-Fi) direct, or infrared data association (IrDA)) or the second network 199 (e.g., a long-range communication network, such as a legacy cellular network, a fifth generation (5G) network, a next-generation communication network, the Internet, or a computer network (e.g., LAN or wide area network (WAN)). These various types of communication modules may be implemented as a single component (e.g., a single chip), or may be implemented as multi components (e.g., multi chips) separate from each other. The wireless communication module 192 may identify and authenticate the electronic device 101 in a communication network, such as the first network 198 or the second network 199, using subscriber information (e.g., international mobile subscriber identity (IMSI)) stored in the subscriber identification module 196.

The wireless communication module 192 may support a 5G network, after a fourth generation (4G) network, and next-generation communication technology, e.g., new radio (NR) access technology. The NR access technology may support enhanced mobile broadband (eMBB), massive machine type communications (mMTC), or ultra-reliable and low-latency communications (URLLC). The wireless communication module 192 may support a high-frequency band (e.g., the millimeter wave (mmWave) band) to achieve, e.g., a high data transmission rate. The wireless communication module 192 may support various technologies for securing performance on a high-frequency band, such as, e.g., beamforming, massive multiple-input and multiple-output (massive MIMO), full dimensional MIMO (FD-MIMO), array antenna, analog beam-forming, or large scale antenna. The wireless communication module 192 may support various requirements specified in the electronic device 101, an external electronic device (e.g., the external electronic device 104), or a network system (e.g., the second network 199). According to an embodiment of the disclosure, the wireless communication module 192 may support a peak data rate (e.g., 20 Gbps or more) for implementing eMBB, loss coverage (e.g., 164 dB or less) for implementing mMTC, or U-plane latency (e.g., 0.5 ms or less for each of downlink (DL) and uplink (UL), or a round trip of 1 ms or less) for implementing URLLC.

The antenna module 197 may transmit or receive a signal or power to or from the outside (e.g., the external electronic device) of the electronic device 101. According to an embodiment of the disclosure, the antenna module 197 may include an antenna including a radiating element including a conductive material or a conductive pattern formed in or on a substrate (e.g., a printed circuit board (PCB)). According to an embodiment of the disclosure, the antenna module 197 may include a plurality of antennas (e.g., array antennas). In such a case, at least one antenna appropriate for a communication scheme used in the communication network, such as the first network 198 or the second network 199, may be selected, for example, by the communication module 190 (e.g., the wireless communication module 192) from the plurality of antennas. The signal or the power may then be transmitted or received between the communication module 190 and the external electronic device via the selected at least one antenna. According to an embodiment of the disclosure, another component (e.g., a radio frequency integrated circuit (RFIC)) other than the radiating element may be additionally formed as part of the antenna module 197.

According to various embodiments of the disclosure, the antenna module 197 may form a mmWave antenna module. According to an embodiment of the disclosure, the mmWave antenna module may include a printed circuit board, an RFIC disposed on a first surface (e.g., the bottom surface) of the printed circuit board, or adjacent to the first surface and capable of supporting a designated high-frequency band (e.g., the mmWave band), and a plurality of antennas (e.g., array antennas) disposed on a second surface (e.g., the top or a side surface) of the printed circuit board, or adjacent to the second surface and capable of transmitting or receiving signals of the designated high-frequency band.

At least some of the above-described components may be coupled mutually and communicate signals (e.g., commands or data) therebetween via an inter-peripheral communication scheme (e.g., a bus, general purpose input and output (GPIO), serial peripheral interface (SPI), or mobile industry processor interface (MIPI)).

According to an embodiment of the disclosure, commands or data may be transmitted or received between the electronic device 101 and the external electronic device 104 via the server 108 coupled with the second network 199. Each of the external electronic devices 102 or 104 may be a device of a same type as, or a different type, from the electronic device 101. According to an embodiment of the disclosure, all or some of operations to be executed at the electronic device 101 may be executed at one or more of the external electronic devices 102 or 104 or the server 108. For example, if the electronic device 101 should perform a function or a service automatically, or in response to a request from a user or another device, the electronic device 101, instead of, or in addition to, executing the function or the service, may request the one or more external electronic devices to perform at least part of the function or the service. The one or more external electronic devices receiving the request may perform the at least part of the function or the service requested, or an additional function or an additional service related to the request, and transfer an outcome of the performing to the electronic device 101. The electronic device 101 may provide the outcome, with or without further processing of the outcome, as at least part of a reply to the request. To that end, a cloud computing, distributed computing, mobile edge computing (MEC), or client-server computing technology may be used, for example. The electronic device 101 may provide ultra low-latency services using, e.g., distributed computing or mobile edge computing. In another embodiment of the disclosure, the external electronic device 104 may include an internet-of-things (IoT) device. The server 108 may be an intelligent server using machine learning and/or a neural network. According to an embodiment of the disclosure, the external electronic device 104 or the server 108 may be included in the second network 199. The electronic device 101 may be applied to intelligent services (e.g., a smart home, a smart city, a smart car, or healthcare) based on 5G communication technology or IoT-related technology.

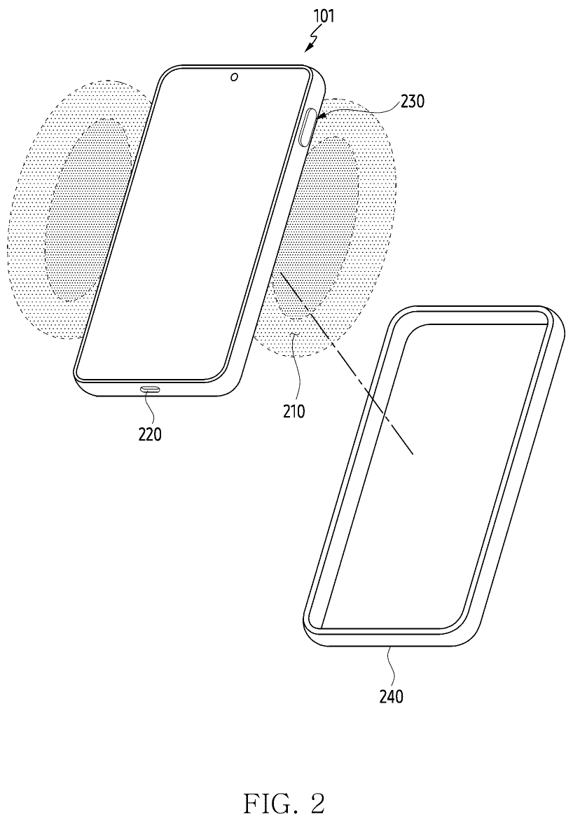

FIG. 2 is a diagram for describing an operation of an electronic device detecting a grip on the electronic device using a grip sensor according to an embodiment of the disclosure. An electronic device 101 of FIG. 2 may include the electronic device 101 of FIG. 1.

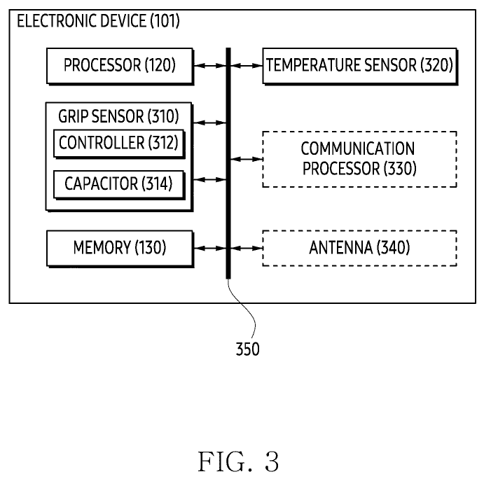

Referring to FIG. 2, a grip sensor (e.g., a grip sensor 310 of FIG. 3) included in the electronic device 101 may form an electric field 210. For example, a capacitor of the grip sensor included in the electronic device 101 may form the electric field 210. The electronic device 101 may detect a grip on the electronic device 101 based on the electric field 210 measured by the grip sensor. The electronic device 101 may identify a grip on the electronic device 101 based on an amount of change in the electric field 210. The electronic device 101 may detect a grip on the electronic device 101 before, during, and/or after occurrence of an event. For example, the electronic device 101 may identify a grip on the electronic device 101 after booting of the electronic device 101 is initiated.

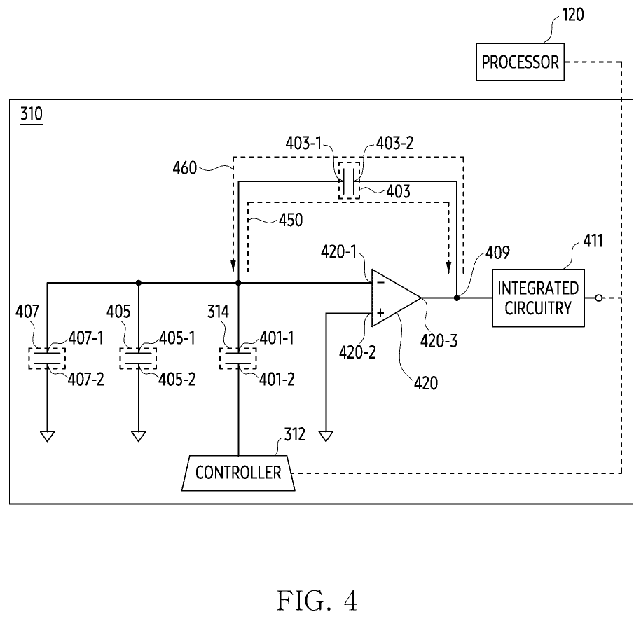

According to an embodiment of the disclosure, the electronic device 101 may detect a grip on the electronic device 101 while an event occurs. The electronic device 101 may identify a grip on the electronic device 101 while an event occurs. The event may cause a reset of the grip sensor. The reset of the grip sensor may include matching a capacitance of a first capacitor (e.g., a first capacitor 314 of FIG. 4) by a processor (e.g., the processor 120 of FIG. 1) to a capacitance obtained based on a capacitance of a third capacitor (e.g., a third capacitor 405 of FIG. 4) and a capacitance of a fourth capacitor (e.g., a fourth capacitor 407 of FIG. 4).

For example, the event may occur based on at least one of establishment of a connection by a port 220 (e.g., the connection terminal 178 of FIG. 1) of the electronic device 101, booting of the electronic device 101, or identification of an external object 240 in contact with the electronic device 101.

For example, the electronic device 101 may establish a connection with an external electronic device (e.g., a charger, a USB device, and so on) by the port 220 (e.g., a USB port, a USB-C port, a lightning port, and so on) of the electronic device 101. The event causing a reset of the grip sensor may include the establishment of the connection. The establishment of the connection with an external electronic device by the port 220 of the electronic device 101 may cause a reset of the grip sensor. The establishment of the connection by the port 220 of the electronic device 101 may change the electric field 210 formed by the grip sensor. The electronic device 101 may identify a grip on the electronic device 101, based on the changed electric field 210 while the connection with an external electronic device by the port 220 of the electronic device 101 is established. The electronic device 101 may identify a grip on the electronic device 101 based on a capacitance stored in memory 130 after the connection by the port 220 of the electronic device 101 is established.

For example, the electronic device 101 may include a button 230 (e.g., the input module 150 of FIG. 1). The electronic device 101 may boot the electronic device 101 based on an input with respect to the button 230. The input with respect to the button 230 may include a gesture of pressing the button 230 for longer than a preset time. The event causing a reset of the grip sensor may include booting of the electronic device 101 based on the input with respect to the button 230. The booting of the electronic device 101 may change the electric field 210 formed by the grip sensor. In response to the booting of the electronic device 101, the electronic device 101 may identify a grip on the electronic device 101 based on the changed electric field 210. For example, the electronic device 101 may identify a grip on the electronic device 101 by the changed electric field 210 based on completion of booting of the electronic device 101. Responding to the completion of booting of the electronic device 101 may mean immediately after the booting of the electronic device 101 is completed. For example, in response to the completion of booting of the electronic device 101, the electronic device 101 may detect release of a grip on the electronic device 101 based on the capacitance of the first capacitor being maintained.

For example, the electronic device 101 may identify the external object 240 (e.g., a cover case of the electronic device 101) including a hall sensor in contact with the electronic device 101. The event causing the reset of the grip sensor may include identification of the external object 240 including the hall sensor in contact with the electronic device 101. The external object 240 in contact with the electronic device 101 may change the electric field 210 formed by the grip sensor. The contact of the external object 240 with the electronic device 101 may cause a reset of the grip sensor. The electronic device 101 may identify a grip on the electronic device 101 based on the changed electric field 210 while identifying the external object 240 in contact with the electronic device 101.

Based on the above-described events, the electronic device 101 may incorrectly detect a grip on the electronic device 101 by a change in the electric field 210 formed by the capacitor included in the grip sensor of the electronic device 101. According to embodiments described later, the electronic device 101 may correctly detect a grip on the electronic device 101 in response to an event occurring in the electronic device 101, by detecting a grip on the electronic device 101 using the capacitance stored in the memory of the electronic device 101. The electronic device 101 may detect a grip on the electronic device 101 after an event occurring in the electronic device 101, by detecting a grip on the electronic device 101 using the capacitance stored in the memory of the electronic device 101.

FIG. 3 illustrates a simplified block diagram of an electronic device according to an embodiment of the disclosure. An electronic device 101 of FIG. 3 may include the electronic device 101 of FIGS. 1 and 2.

Referring to FIG. 3, according to an embodiment of the disclosure, the processor 120, a grip sensor 310, memory 130, a temperature sensor 320, a communication processor 330, an antenna 340 may be electronically and/or operably coupled with each other by an electronical component, such as a communication bus 350. According to an embodiment of the disclosure, the grip sensor 310 may include a controller 312 and/or a first capacitor 314. Although illustrated based on different blocks, the embodiment is not limited thereto. For example, a portion (e.g., at least a portion of the processor 120, the grip sensor 310, the memory 130, and/or the temperature sensor 320) of hardware component illustrated in FIG. 3 may be included in a single integrated circuit, such as a system on a chip (SoC). The type and/or number of hardware component included in the electronic device 101 are not limited to those illustrated in FIG. 3. For example, the electronic device 101 may include only a portion of the hardware component illustrated in FIG. 3. According to an embodiment of the disclosure, the electronic device 101 may omit the communication processor 330 and the antenna 340.

According to an embodiment of the disclosure, the processor 120 of the electronic device 101 may include a hardware component for processing data based on one or more instructions. The hardware component for processing data may include, for example, an arithmetic and logic unit (ALU), a floating point unit (FPU), a field programmable gate array (FPGA), an application processor (AP), and/or a central processing unit (CPU). The number of the processor 120 may be one or more. For example, the processor 120 may have a structure of a multi-core processor, such as a dual core, a quad core, or a hexa core. For example, the processor 120 may have a structure of a single-core processor, such as a single core. The processor 120 of FIG. 2 may include the processor 120 of FIG. 1. For example, the processor 120 may detect a grip on the electronic device 101 based on a signal transmitted from the grip sensor 310.

According to an embodiment of the disclosure, the memory 130 of the electronic device 101 may include a hardware component for storing data and/or instruction inputted and/or outputted to the processor 120. The memory 130 may include, for example, volatile memory, such as random-access memory (RAM) and/or non-volatile memory, such as read-only memory (ROM). The volatile memory may include, for example, at least one of dynamic RAM (DRAM), static RAM (SRAM), cache RAM, and pseudo SRAM (PSRAM). The nonvolatile memory may include, for example, at least one of programmable ROM (PROM), erasable PROM (EPROM), electrically erasable PROM (EEPROM), flash memory, a hard disk, a compact disk, and an embedded multimedia card (eMMC). The memory 130 of FIG. 3 may include the memory 130 of FIG. 1. For example, the memory 130 may store a capacitance of the first capacitor 314.

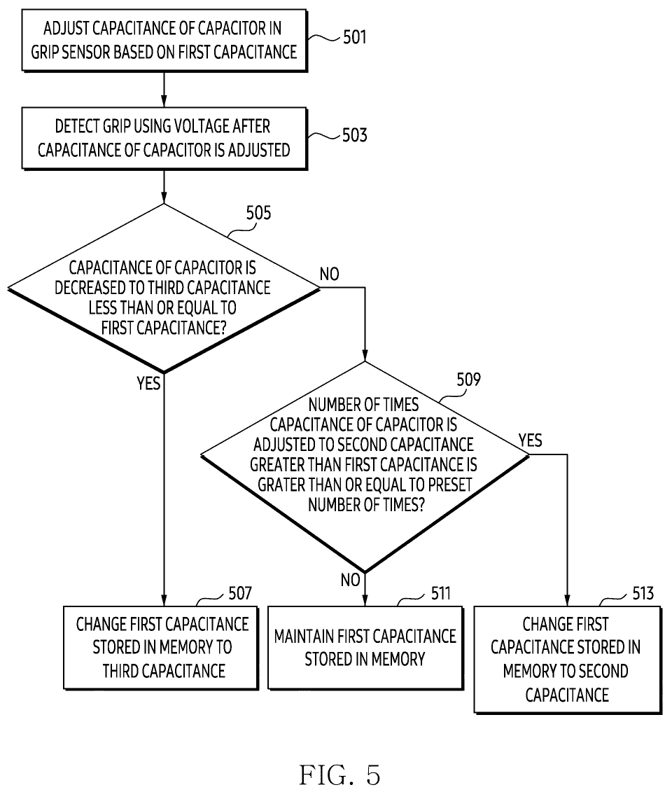

In the memory 130, one or more instructions indicating calculation and/or operation to be performed on data by the processor 120 may be stored. A set of one or more instructions may be referred to as a firmware, an operating system, a processor, a routine, a sub-routine and/or an application. For example, the electronic device 101 and/or the processor 120 may perform, when a set of a plurality of instructions distributed in a form of an operating system, a firmware, a driver, and/or an application is executed, at least one of operations of FIG. 5, 6, or 8. Hereinafter, an application being installed in the electronic device 101 may mean that one or more instructions provided in a form of an application are stored in the memory 130 of the electronic device 101, and the one or more applications are stored in a format (e.g., a file with a preset extension by the operating system of the electronic device 101) executable by the processor 120 of the electronic device 101.

According to an embodiment of the disclosure, the grip sensor 310 of the electronic device 101 may detect a grip on a housing of the electronic device 101. The grip on the housing may occur by a movement (e.g., a gesture grasping the electronic device 101) of a body part (e.g., a user's hand). The grip sensor 310 may detect the grip using a change in a capacitance and/or an electric field (e.g., the electric field 210 of FIG. 2) formed on at least a portion (e.g., a surface of the housing) of the housing. The first capacitor 314 included in the grip sensor 310 may form the electric field 210. The first capacitor 314 of the grip sensor 310 may form the electric field 210. The electric field 210 and/or the capacitance may be changed by a movement of the body part adjacent to the electronic device 101. Based on an electrical signal indicating the electric field 210 and/or the capacitance obtained from the grip sensor 310, the processor 120, the communication processor 330, and/or the controller 312 included in the grip sensor 310 may identify the grip. For example, the processor 120 may identify a grip on the electronic device 101 based on the capacitance detected by the grip sensor 310. For example, the processor 120 may identify a grip on the electronic device 101 based on the capacitance of the first capacitor 314 included in the grip sensor 310, detected by the grip sensor 310. For example, the processor 120, the communication processor 330, and/or the controller 312 may identify the grip based on the electric field 210 and/or the capacitance indicated by the electrical signal. According to an embodiment of the disclosure, operation in which the electronic device 101 detects a grip on the electronic device 101 based on sensor data of a sensor (e.g., the temperature sensor 320) different from the grip sensor 310 will be described later.

According to an embodiment of the disclosure, the communication processor 330 may correspond to at least a portion of the communication module 190 of FIG. 1. For example, the communication processor 330 may be used for various radio access technologies (RATs). For example, the communication processor 330 may be used to perform Bluetooth communication or wireless local area network (WLAN) communication. For example, the communication processor 330 may be used to perform cellular communication. For example, the processor 120 may establish a connection with an external electronic device through the communication processor 330. For example, the processor 120 may establish a connection with a server through the communication processor 330.

According to an embodiment of the disclosure, the antenna 340 may transmit or receive a signal or power to or from an outside (e.g., an external electronic device). According to an embodiment of the disclosure, the antenna 340 may include an antenna including a conductor formed on a substrate (e.g., a PCB) or a radiator made of a conductive pattern. According to an embodiment of the disclosure, the antenna 340 may include a plurality of antennas (e.g., an array antenna). The antenna 340 of FIG. 3 may include the antenna module 197 of FIG. 1.

According to an embodiment of the disclosure, the processor 120 may identify a grip on the electronic device 101. The processor 120 may adjust intensity of a wireless signal radiated to the outside through the communication processor 330, based on detection of a grip on the electronic device 101.

According to an embodiment of the disclosure, the electronic device 101 may detect a grip on the electronic device based on a capacitance stored in the memory 130 and a preset node included in the grip sensor 310. The electronic device 101 may reduce the intensity of the wireless signal radiated to the outside through the communication processor 330 based on the grip on the electronic device 101 detected based on the capacitance and the preset node. The electronic device 101 may provide an effect that satisfies SAR, by reducing the intensity of the wireless signal based on the grip being detected.

For example, in case of detecting a grip of the electronic device 101 without using the capacitance stored in the memory 130, the electronic device 101 may incorrectly detect the grip on the electronic device 101 in response to performing a reset (e.g., a booting of the electronic device 101) of the grip sensor 310. Even in a case where the reset of the grip sensor 310 is performed by a preset event occurring in the electronic device, the electronic device 101 according to the described above may detect the grip on the electronic device 101 in response to performing the reset of the grip sensor 310, by detecting the grip on the electronic device 101 based on the capacitance stored in the memory 130 and a voltage of the preset node included in the grip sensor 310.

FIG. 4 illustrates at least a portion of a circuit included in a grip sensor of an electronic device according to an embodiment of the disclosure. An electronic device of FIG. 4 may include the electronic device 101 of FIGS. 1 to 3. For example, a processor 120 of FIG. 4 may include the processor 120 of FIG. 1 to the processor 120 of FIG. 3. A grip sensor 310 of FIG. 4 may include the grip sensor 310 of FIG. 3. A controller 312 of FIG. 4 may include the controller 312 of FIG. 3.

Referring to FIG. 4, according to an embodiment of the disclosure, the grip sensor 310 may include an amplifier 420, a first capacitor 314, a second capacitor 403, a third capacitor 405, and/or integrated circuitry 411.

According to an embodiment of the disclosure, the grip sensor 310 may include the amplifier 420 including a noninverted input 420-2 that is grounded, an inverted input 420-1 connected to an end 401-1 of the first capacitor 314, and an output node 420-3 connected to a preset node 409. The noninverted input 420-2 of the amplifier 420 may be grounded. The output node 420-3 of the amplifier 420 may be connected to the preset node 409.

The end 401-1 of the first capacitor 314 may be connected to the inverted input 420-1 of the amplifier 420. An end 401-2 of the first capacitor 314 may be connected to the controller 312. The controller 312 may charge the first capacitor 314.

An end 403-1 of the second capacitor 403 may be connected to the inverted input 420-1 of the amplifier 420. An end 403-2 of the second capacitor 403 may be connected to the output node 420-3 of the amplifier 420 and/or the preset node 409. The end 403-2 of the second capacitor 403 may be connected to the integrated circuitry 411. For example, the second capacitor 403 may adjust the sensitivity of the grip sensor.

An end 405-1 of the third capacitor 405 may be connected to the inverted input 420-1 of the amplifier 420. The end 405-1 of the third capacitor 405 may be connected to the end 401-1 of the first capacitor 314 and/or the end 403-1 of the second capacitor 403. An end 405-2 of the capacitor 405 may be grounded. A capacitance of the third capacitor 405 may vary according to temperature. The capacitance of the third capacitor 405 may vary according to humidity. The capacitance of the third capacitor 405 may have the same value according to time. For example, the capacitance of the third capacitor 405 may have the same value within a state where a temperature and/or humidity are the same. The capacitance of the third capacitor 405 according to an embodiment may be different from a capacitance of a third capacitor of an external electronic device substantially the same as the electronic device 101.

The fourth capacitor 407 is an equivalent circuit of an external object to describe a capacitance adjusted by the external object (e.g., a user's finger, and so on) in an electric field (e.g., the electric field 210 of FIG. 2) formed by the third capacitor 405. The fourth capacitor 407 may include an end 407-1 connected to the inverted input 420-1 of the amplifier 420 and another end 407-2 that is grounded. The capacitance of the fourth capacitor 407 may occur by an external object. For example, the processor 120 may detect a grip on the electronic device 101, based on the capacitance of the fourth capacitor 407 that occurs based on the external object.

The preset node 409 may include a node for outputting a voltage for detecting a grip on the electronic device 101. The preset node 409 may be connected to the output node 420-3 of the amplifier 420. The preset node 409 may be connected to the integrated circuitry 411. The preset node 409 may be connected to the integrated circuitry 411 including a digital signal generator. The preset node 409 may be connected to the output node 420-3.

A voltage of the preset node 409 may be changed based on a change in the capacitance of the third capacitor 405 and/or the capacitance of the fourth capacitor 407. The electronic device may identify the voltage outputted to the preset node 409 based on the capacitance of the third capacitor 405, the capacitance of the fourth capacitor 407, and/or the capacitance of the second capacitor 403. The electronic device may detect a grip on the electronic device based on the outputted voltage. For example, the electronic device may store the voltage of the preset node 409 and the capacitance of the first capacitor 314, based on maintaining the voltage of the preset node 409 at a predetermined voltage. The electronic device may detect a grip on the electronic device based on identifying that the voltage of the preset node 409 changed based on the capacitance of the fourth capacitor 407 caused by an external object is greater than or equal to a preset range.

The integrated circuitry 411 may be connected to the output node 420-3 and/or the preset node 409. The integrated circuitry 411 may be connected to the processor 120. The integrated circuitry 411 may be connected to the controller 312. The integrated circuitry 411 may include a digital signal generator. The integrated circuitry 411 may output an electrical signal transmitted from the amplifier 420 by converting the electrical signal into a digital signal. The integrated circuitry 411 may transmit the outputted digital signal to the processor 120 and/or the controller 312. The integrated circuitry 411 may obtain a digital value based on a voltage of the preset node. The digital value may be changed based on the adjustment of the voltage of the preset node. For example, the electronic device may detect release of a grip on the electronic device, based on identifying the digital value as 0. For example, the electronic device may detect a grip on the electronic device based on identifying the digital value as a positive number. For example, the electronic device may transmit a signal for performing a reset of the grip sensor to the grip sensor, based on identifying the digital value as a negative number. As an example, the processor may transmit a signal for performing a reset of the grip sensor to the controller of the grip sensor, based on identifying the digital value as a negative number. The electronic device may adjust the capacitance of the first capacitor 314 to match a composite capacitance of the third capacitor 405 and the fourth capacitor 407, based on performing a reset of the grip sensor. The composite capacitance may be a sum of the capacitance of the third capacitor 405 and the capacitance of the fourth capacitor 407.

According to an embodiment of the disclosure, in case that the composite capacitance of the third capacitor 405 and the fourth capacitor 407 is greater than the capacitance of the first capacitor 314, a current may flow from the first capacitor 314 toward the second capacitor 403. For example, the current may flow in a first direction 450 from the first capacitor 314 through the second capacitor 403 to the preset node 409. In case that the current flows in the first direction 450, the current may cause discharge of the first capacitor 314. The current may cause an increase in the voltage of the preset node 409. The electronic device may identify a grip on the electronic device based on the increase in the voltage.

According to an embodiment of the disclosure, in case that the composite capacitance is less than the capacitance of the first capacitor 314, a current may flow from the second capacitor 403 toward the first capacitor 314. For example, the current may flow in a second direction 460 from the preset node 409 through the second capacitor 403 to the first capacitor 314. In case that the current flows in the second direction 460, the current may cause charging of the first capacitor 314. The current may cause a decrease in the voltage of the preset node 409. The electronic device may transmit a signal for performing a reset of the grip sensor 310 based on the decrease in the voltage.

According to an embodiment of the disclosure, in case that the composite capacitance matches the capacitance of the first capacitor 314, a state in which no current flows in the preset node 409 may be maintained. Based on the state, the voltage of the preset node 409 may be maintained at a constant voltage. The electronic device may identify that the grip on the electronic device has been released, based on a state in which the constant voltage is maintained.

According to an embodiment of the disclosure, the electronic device may adjust the capacitance of the first capacitor 314 in the grip sensor 310, based on the first capacitance stored in memory and/or a register. The electronic device may detect a grip on the electronic device while a reset of the grip sensor is performed, based on the capacitance of the first capacitor 314 adjusted to the first capacitance and the voltage (or change in the voltage) of the preset node 409.

FIG. 5 illustrates a flowchart regarding an operation of an electronic device according to an embodiment of the disclosure. The electronic device of FIG. 5 may include the electronic device 101 of FIG. 1 to the electronic device 101 of FIG. 3. A processor of FIG. 5 may include the processor 120 of FIG. 1, and the processor 120 of FIG. 3 to the processor 120 of FIG. 4. A grip sensor of FIG. 5 may include the grip sensor 310 of FIG. 3 to the grip sensor 310 of FIG. 4. A controller of FIG. 5 may include the controller 312 of FIG. 3 to the controller 312 of FIG. 4. A first capacitor of FIG. 5 may include the first capacitor 314 of FIG. 3 to the first capacitor 314 of FIG. 4. Operations of FIG. 5 may be performed by the electronic device 101 of FIG. 3 (e.g., at least one of the processor 120 or the controller 312 of the grip sensor 310).

Referring to FIG. 5, in operation 501, according to an embodiment of the disclosure, the electronic device may adjust a first capacitor (e.g., the first capacitor 314 of FIG. 3) in a grip sensor (e.g., the grip sensor 310 of FIG. 3) based on a first capacitance. For example, the electronic device may adjust a capacitance of the first capacitor in the grip sensor to change a voltage outputted from the grip sensor, based on the first capacitance stored in the electronic device. The first capacitance may be stored in memory (e.g., the memory 130 of FIG. 3) and/or a register (e.g., a register in the controller 312 of FIG. 3) of the electronic device.

According to an embodiment of the disclosure, the processor may adjust the capacitance of the first capacitor in the grip sensor by controlling a controller of the grip sensor. The controller of the grip sensor may receive, from the processor, a signal for adjusting the capacitance of the first capacitor in the grip sensor. The controller of the grip sensor may adjust the capacitance of the first capacitor based on reception of the signal.

According to an embodiment of the disclosure, the electronic device may identify a voltage of a preset node while adjusting the capacitance of the first capacitor. The electronic device may store the capacitance of the first capacitor, the voltage of the preset node, and/or a digital value transmitted through the integrated circuitry when the voltage of the preset node is maintained for a preset time.

In operation 503, according to an embodiment of the disclosure, the electronic device may detect a grip using a voltage, after the capacitance of the first capacitor is adjusted. For example, the electronic device may adjust the capacitance of the first capacitor from the first capacitance to a second capacitance. The second capacitance may include the capacitance of the first capacitor (e.g., the first capacitor 314 of FIG. 4). The electronic device may use a voltage changed by the first capacitor after the capacitance of the first capacitor is adjusted to the second capacitance greater than the first capacitance. The electronic device may detect a grip on the electronic device, based on the voltage changed by the first capacitor.

In operation 505, the electronic device may identify whether the capacitance of the first capacitor is decreased to a third capacitance less than or equal to the first capacitance. For example, the electronic device may store the first capacitance and/or the third capacitance in the memory. The electronic device may identify whether the capacitance of the first capacitor is decreased to the third capacitance less than or equal to the first capacitance.

In case that the capacitance of the first capacitor is decreased to the third capacitance less than or equal to the first capacitance (505-Yes), in operation 507, when the capacitance of the first capacitor is decreased to the third capacitance less than or equal to the first capacitance, the electronic device may change the first capacitance stored in the memory and/or register (e.g., a register in the controller 312 of FIG. 3) of the electronic device to the third capacitance. For example, the electronic device may identify that the capacitance of the first capacitor is decreased to the third capacitance less than or equal to the first capacitance, based on the discharge of the first capacitor. The electronic device may adjust the first capacitance to the third capacitance, based on the capacitance of the first capacitor being decreased to the third capacitance. The electronic device may detect a grip on the electronic device based on the adjusted third capacitance.

In case that the capacitance of the first capacitor is not decreased to the third capacitance less than or equal to the first capacitance (505-No), in operation 509, the electronic device may identify whether the number of times the capacitance of the first capacitor is adjusted to be less than or equal to the second capacitance, which is greater than the first capacitance, is a preset number of times. For example, while the capacitance of the first capacitor changes based on charging and discharging of the capacitor, the electronic device may identify that the number of times the capacitance of the first capacitor is adjusted to be less than or equal to the second capacitance, which is greater than the first capacitance, matches the preset number of times.

In case that the number of times the capacitance of the first capacitor is adjusted to be less than or equal to the second capacitance is less than the preset number of times (509-No), in operation 511, according to an embodiment of the disclosure, the electronic device may maintain the first capacitance stored in the memory. For example, the electronic device may maintain the first capacitance stored in the memory and/or register, based on the number of times the capacitance of the first capacitor is adjusted to be less than or equal to the second capacitance, which is greater than the first capacitance, being less than the preset number of times.

In case that the number of times the capacitance of the first capacitor is adjusted to be less than or equal to the second capacitance is greater than or equal to the preset number of times (509-Yes), in operation 513, according to an embodiment of the disclosure, the electronic device may change the first capacitance stored in the memory (e.g., the memory 130 of FIG. 3) and/or the register (e.g., the register in the controller 312 of FIG. 3) of the electronic device to the second capacitance. For example, the electronic device may adjust the first capacitance stored in the memory and/or register to the second capacitance, based on the number of times the capacitance of the first capacitor is adjusted to be less than or equal to the second capacitance, which is greater than the first capacitance, matching the preset number of times.

According to an embodiment of the disclosure, in response to occurrence of a preset event in which the capacitance of the first capacitor is adjusted to the second capacitance, which is greater than the first capacitance, the electronic device may detect a grip on the electronic device based on the first capacitance stored in the memory and/or the register, and a voltage outputted from the grip sensor. For example, the electronic device may identify the occurrence of the preset event. As an example, the preset event may include establishing a connection with an external device by a port (e.g., the port 220 of FIG. 2) of the electronic device. As an example, the preset event may include booting the electronic device based on an input that exceeds a preset time for a button (e.g., the button 230 of FIG. 2) of the electronic device. The electronic device may identify a grip on the electronic device using the first capacitance, based on the booting of the electronic device. As an example, the preset event may include identifying a contact of an external object (e.g., the external object 240 of FIG. 2) including a hall sensor in the electronic device. As an example, based on establishment of a connection by the port of the electronic device, the electronic device may detect a grip on the electronic device based on the first capacitance stored in the memory and/or register, and the voltage outputted from the grip sensor, while the capacitance of the first capacitor is adjusted to the second capacitance.

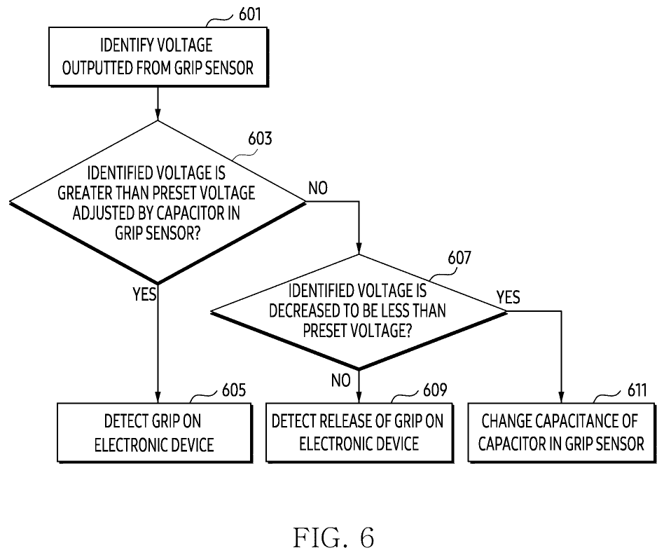

FIG. 6 illustrates a flowchart regarding an operation of an electronic device according to an embodiment of the disclosure. The electronic device of FIG. 6 may include the electronic device 101 of FIG. 1 to the electronic device 101 of FIG. 3. A processor of FIG. 6 may include the processor 120 of FIG. 1, and the processor 120 of FIG. 3 to the processor 120 of FIG. 4. A grip sensor of FIG. 6 may include the grip sensor 310 of FIG. 3 to the grip sensor 310 of FIG. 4. A controller of FIG. 6 may include the controller 312 of FIG. 3 to the controller 312 of FIG. 4. A first capacitor of FIG. 6 may include the first capacitor 314 of FIG. 3 to the first capacitor 314 of FIG. 4. Operations of FIG. 6 may be performed by the electronic device 101 of FIG. 3 (e.g., at least one of the processor 120 or the controller 312 of the grip sensor 310).

Referring to FIG. 6, in operation 601, according to an embodiment of the disclosure, the electronic device may identify a voltage outputted from a grip sensor. For example, the electronic device may identify a voltage of a preset node (e.g., the preset node 409 of FIG. 4). The electronic device may identify the voltage of the preset node that is changed based on charging of a first capacitor (e.g., the first capacitor 314 of FIG. 4) and/or discharging of the first capacitor.

In operation 603, according to an embodiment of the disclosure, the electronic device may identify whether the identified voltage is greater than a preset voltage adjusted by the first capacitor in the grip sensor. For example, the electronic device may identify whether the voltage of the preset node changed based on the charging of the first capacitor and/or the discharging of the first capacitor is greater than the preset voltage.

In case that the identified voltage is greater than the preset voltage adjusted by the first capacitor in the grip sensor (603-Yes), in operation 605, the electronic device may detect a grip on the electronic device. For example, the electronic device may detect a grip on the electronic device, based on the voltage of the preset node, which is obtained based on the charging of the first capacitor and/or the discharging of the first capacitor, is greater than the preset voltage.

In case that the identified voltage is not greater than the preset voltage adjusted by the first capacitor in the grip sensor (603-No), in operation 607, according to an embodiment of the disclosure, the electronic device may identify whether the identified voltage decreases below the preset voltage. For example, the electronic device may identify the voltage of the preset node, while the voltage of the preset node is changed based on the charging of the first capacitor and/or the discharging of the capacitor.

In case that the identified voltage does not decrease below the preset voltage (607-No), in operation 609, according to an embodiment of the disclosure, the electronic device may detect release of a grip on the electronic device. For example, the electronic device may detect the release of a grip on the electronic device based on the voltage of the preset node. For example, in case that the voltage of the preset node obtained based on the charging of the first capacitor and/or the discharging of the first capacitor matches the preset voltage, the electronic device may detect the release of a grip on the electronic device. The electronic device may detect the release of a grip on the electronic device, based on identifying that the voltage of the preset node decreases to the preset voltage.

In case that the identified voltage is decreased to less than the preset voltage (607-Yes), in operation 611, according to an embodiment of the disclosure, the electronic device may change a capacitance of the first capacitor in the grip sensor. For example, the electronic device may change the capacitance of the first capacitor in the grip sensor, based on identifying that the voltage of the preset node is less than the preset voltage. For example, the processor may transmit a signal to perform a reset of the grip sensor to a controller of the grip sensor, based on identifying that the identified voltage is less than the preset voltage. In response to the reset of the grip sensor, the electronic device may adjust the capacitance of the first capacitor based on the first capacitance stored in memory and/or a register. For example, in response to the reset of the grip sensor, the electronic device may detect a grip on the electronic device, based on the capacitance adjusted to the first capacitance.

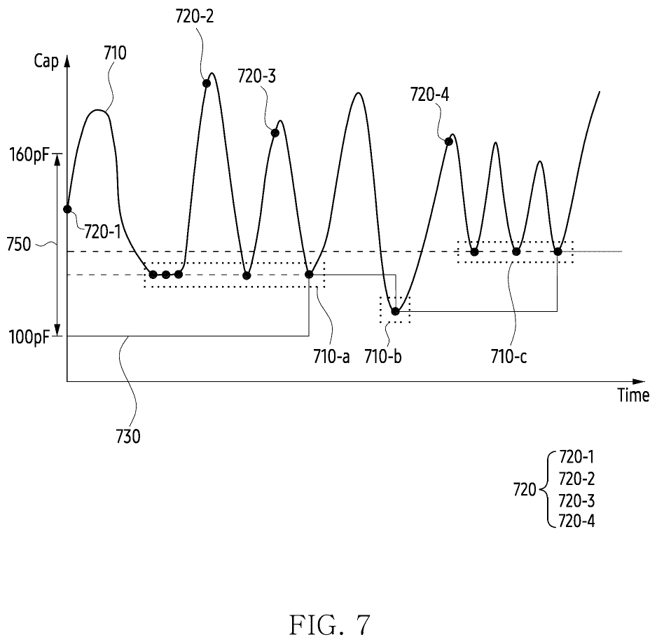

FIG. 7 illustrates a range indicated by a capacitance of a first capacitor and a capacitance stored in memory or a controller according to an embodiment of the disclosure.

Referring to FIG. 7, an electronic device may include the electronic device 101 of FIG. 1 to the electronic device 101 of FIG. 3. A processor of FIG. 7 may include the processor 120 of FIG. 1, and the processor 120 of FIG. 3 to the processor 120 of FIG. 4. A grip sensor of FIG. 7 may include the grip sensor 310 of FIG. 3 to the grip sensor 310 of FIG. 4. A controller of FIG. 7 may include the controller 312 of FIG. 3 to the controller 312 of FIG. 4. An amplifier of FIG. 7 may include the amplifier 420 of FIG. 4. A preset node of FIG. 7 may include the preset node 409 of FIG. 4. Operations of FIG. 7 may be performed by the electronic device 101 of FIG. 3 (e.g., at least one of the processor 120 or the controller 312 of the grip sensor 310). A first capacitor of FIG. 7 may include the first capacitor 314 of FIG. 3 to the first capacitor 314 of FIG. 4. A second capacitor of FIG. 7 may include the third capacitor 405 of FIG. 4. A third capacitor of FIG. 7 may include the fourth capacitor 407 of FIG. 4. FIG. 7 illustrates a composite capacitance 710 obtained based on a capacitance of the second capacitor and a capacitance of the third capacitor. FIG. 7 illustrates a capacitance 730 stored in one of the memory or the controller. FIG. 7 illustrates a range 750 indicated by the capacitance 730 stored in the memory. For example, the capacitance 730 may be adjusted within 100 [pF] to 160 [pF]. For example, the capacitance 730 may be related to a first capacitance of Table 2 described below. The capacitance 730 may vary according to temperature.

Referring to FIG. 7, according to an embodiment of the disclosure, the electronic device may obtain the composite capacitance 710 based on the capacitance of the second capacitor and the capacitance of the third capacitor. The electronic device may detect a grip on the electronic device based on the composite capacitance 710. The electronic device may adjust a capacitance of the first capacitor to capacitances 720 of a case where an event occurred. For example, the capacitances 720 may be adjusted by the electronic device at a time point when the grip sensor is reset. For example, a capacitance 720-1 may include a capacitance identified in response to booting of the electronic device, based on an input that exceeds a preset time for a button (e.g., the button 230 of FIG. 2) included in the electronic device. For example, a capacitance 720-2 may include a capacitance identified when a connection of an external device with respect to a port (e.g., the port 220 of FIG. 2) included in the electronic device is established. The electronic device may maintain the first capacitance and/or the third capacitance stored in memory and/or a register (e.g., the register in the controller 312 of FIG. 3), based on release of the establishment of the connection by the port of the electronic device. For example, a capacitance 720-3 may include a capacitance of the first capacitor obtained in a rebooted state of the electronic device 101. For example, a capacitance 720-4 may include a capacitance identified when a contact of an external object (e.g., the external object 240 of FIG. 2) including a hall sensor is identified in the electronic device.

According to an embodiment of the disclosure, in case that the capacitance of the first capacitor has local minimum values that match a preset number of times, the electronic device may change the capacitance of the first capacitor to match the identified local minimum values. For example, in case that the capacitance of the first capacitor has local minimum values 710-a matching a preset number, the electronic device may change the capacitance of the first capacitor to a capacitance matching the local minimum values 710-a. For example, in case that the capacitance of the first capacitor has local minimum values 710-c different from the matching local minimum values 710-a, the electronic device may change the capacitance of the first capacitor adjusted to the capacitance matching the local minimum values 710-a to a capacitance matching the local minimum values 710-c.

According to an embodiment of the disclosure, when the composite capacitance 710 is identified as being smaller than the capacitance of the first capacitor, the electronic device may adjust the capacitance 730 to match the capacitance of the first capacitor. For example, when the capacitance of the first capacitor matching the local minimum values 710-a is identified as a capacitance 710-b lower than the capacitance matching the local minimum values 710-a, the electronic device may adjust the capacitance 730 stored in the memory/or register to match the capacitance 710-b.

According to an embodiment of the disclosure, the electronic device may detect a grip on the electronic device 101 based on the capacitance 730 and a voltage outputted from the grip sensor 310. The electronic device may detect a grip on the electronic device based on the capacitance 730 and a voltage of a preset node. The electronic device may detect a grip on the electronic device 101 based on the capacitance 730 and a signal transmitted from an integrated circuitry. The electronic device may detect a grip on the electronic device based on the capacitance 730 and a signal transmitted from a digital signal generator included in the integrated circuitry.

TABLE 1

| n | Cap [pF] | Time [min] |
|---|---|---|
| 1 | 140 | 0 |
| 2/3/4 | 125.6 | 50 |
| 5 | 180.9 | 235 |
| 6 | 125.6 | 575 |
| 7 | 168 | 620 |
| 8 | 125.6 | 680 |
| 9 | 112.5 | 720 |
| 10 | 162.4 | 780 |
| 11 | 130 | 810 |
| 12 | 130 | 840 |
| 13 | 130 | 855 |

The above Table 1 may include the composite capacitance 710 obtained based on the capacitance of the second capacitor and the capacitance of the third capacitor. The n in the Table 1 may match values shown in the graph illustrated in FIG. 7. In a case of n=1 to n=13 in the Table 1 may include a situation in which the grip sensor 310 performs a reset. A Cap value in the Table 1 may include the capacitance of the first capacitor. The Cap value in the Table 1 may include the capacitance of the first capacitor when the grip sensor is reset. The n in the Table 1 may be related to a preset number of times for adjusting the capacitance of the first capacitor. According to an embodiment of the disclosure, the electronic device may perform a reset of the grip sensor. The electronic device may obtain a capacitance based on the reset of the grip sensor. The electronic device may detect a grip on the electronic device, based on the obtained capacitance.

For example, when identifying the same Cap value consecutively, such as a case of n=2/3/4 in the Table 1, the electronic device may maintain the capacitance 730 stored in the memory and/or register. For example, the electronic device may identify the Cap value based on a reset of the grip sensor. The electronic device may identify one time of the preset number of times based on consecutively identifying the same Cap value within a preset time. The preset time may be a relatively short time compared to a time at which capacitances matching the local minimum values 710-c are identified.

For example, a case of n=2/3/4 in the Table 1 may include a case where the electronic device obtains a repeated Cap value. For example, the case of obtaining the repeated Cap value may include a situation in which the display is repeatedly touched by a user of the electronic device in a state that the electronic device is fixed on the table. For example, when the electronic device identifies the Cap value, the case of n=2/3/4 in the Table 1 may be identified as 1 time in the number of times. The number of times may be included in the preset number of times. For example, the electronic device may change the capacitance 730 to match the Cap value, when identifying the same Cap value more than the preset number of times, such as a case of n=2/3/4, a case of n=6, and a case of n=8 in the Table 1. For example, within a state in which the capacitance 730 is adjusted to 100 [pF], the electronic device may adjust the capacitance 730 to 125.6 [pF] based on identifying the same Cap value (e.g., 125.6 [pF] in the case of n=2/3/4, n=6, and n=8) the preset number of times. According to an embodiment of the disclosure, when identifying the capacitance of the capacitor to be less than the capacitance 730 stored in the memory and/or register, the electronic device may change the stored capacitance 730 to the identified capacitance. For example, the electronic device may change the capacitance 730 to match the Cap value identified in the case of n=9 in the Table 1, based on identifying 112.5 [pF], which is the Cap value in the case of n=9 in the Table 1, being identified to be less than 125.6 [pF], which is the Cap value in the case of n=8 in the Table 1. The electronic device according to an embodiment may change the capacitance 730 to match the Cap value, based on identifying the Cap value matched more than a preset number of times (e.g., three times), such as a case of n=11 to n=13. For example, within a state where the capacitance 730 is adjusted to 125.6 [pF], the electronic device may change the capacitance 730 to 130 [pF] based on the composite capacitance 710 being identified as 130 [pF] for a preset number of times (e.g., three times).

TABLE 2

| Temperature[° C.] | Cap [pF] |
|---|---|
| −20 | 80 |
| −10 | 90 |
| 0 | 95 |
| 10 | 100 |
| 20 | 105 |
| 30 | 110 |
| 40 | 115 |

The Table 2 is an example with respect to parameters mapped to different temperatures in the memory and/or register. The parameters mapped to different temperatures shown in the Table 2 are only examples, and are not limited to the above-described example. According to an embodiment of the disclosure, the electronic device may include a temperature sensor (e.g., the temperature sensor 320 of FIG. 3) for measuring a temperature of the grip sensor. The electronic device may obtain the temperature of the grip sensor through the temperature sensor. The electronic device may store the parameters mapped to different temperatures in the memory and/or register. The electronic device may identify the first capacitance based on a parameter matching the obtained temperature among the parameters stored in the memory and/or a register and mapped to different temperatures. The electronic device may identify that the capacitance of the capacitor is decreased to the third capacitance less than or equal to the first capacitance. The electronic device may change the first capacitance to a parameter matching the identified temperature among the parameters, based on identifying that the capacitance of the capacitor is decreased to the third capacitance.

For example, when the temperature of the grip sensor is identified as 10° C., the electronic device may adjust the capacitance of the first capacitor to 100 [pF], which is a Cap value matching 10° C. For example, when the temperature of the grip sensor is identified as 15° C., the electronic device may adjust the capacitance of the first capacitor to 102.5 [pF], which is an intermediate value between the Cap value matching 10° C. and a Cap value matching 20° C. The electronic device may detect a grip on the electronic device based on the adjusted capacitance.

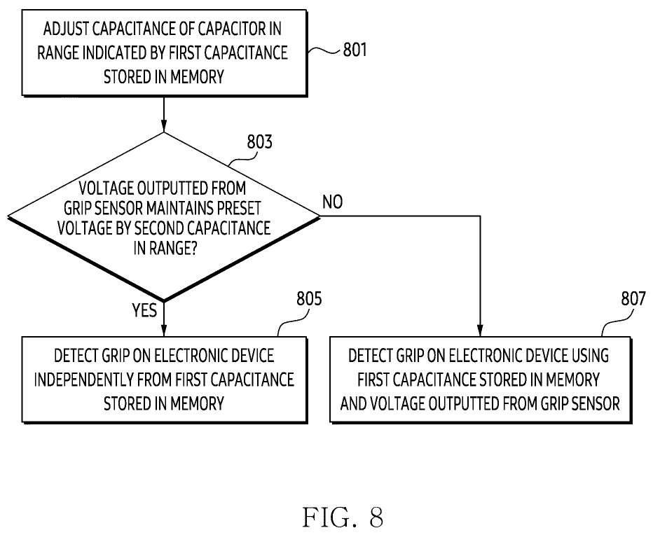

FIG. 8 illustrates a flowchart regarding an operation of an electronic device according to an embodiment of the disclosure. An electronic device of FIG. 8 may include the electronic device 101 of FIG. 1 to the electronic device 101 of FIG. 3. A processor of FIG. 8 may include the processor 120 of FIG. 1, the processor 120 of FIG. 3, and/or the processor 120 of FIG. 4. A grip sensor of FIG. 8 may include the grip sensor 310 of FIG. 3 to the grip sensor 310 of FIG. 4. A controller of FIG. 8 may include the controller 312 of FIG. 3 to the controller 312 of FIG. 4. A capacitor of FIG. 8 may include the capacitor 314 of FIG. 3 to the capacitor 314 of FIG. 4. An amplifier of FIG. 8 may include the amplifier 420 of FIG. 4. A preset node of FIG. 8 may include the preset node 409 of FIG. 4. Operations of FIG. 8 may be performed by the electronic device 101 of FIG. 3 (e.g., at least one of the processor 120 or the controller 312 of the grip sensor 310). An electronic device 101 of FIG. 8 may include the electronic device 101 of FIG. 3 to the electronic device 101 of FIG. 4. A range indicated by a first capacitance of FIG. 8 may include the range 750 indicated by the capacitance 730 stored in the memory of FIG. 7.

Referring to FIG. 8, in operation 801, according to an embodiment of the disclosure, the electronic device may adjust a capacitance of a capacitor (e.g., the capacitor 314 of FIG. 4) within a range indicated by the stored first capacitance (hereinafter, range). For example, the electronic device may store a range. The electronic device may adjust a capacitance of a capacitor in a grip sensor based on the stored range.

In operation 803, according to an embodiment of the disclosure, the electronic device may identify whether a voltage outputted from the grip sensor maintains a preset voltage (e.g., 1.5 V) by a second capacitance within the range. For example, the electronic device may identify whether a voltage of a preset node (e.g., the preset node 409 of FIG. 4) maintains the preset voltage.

In case that the voltage outputted from the grip sensor maintains the preset voltage by the second capacitance within the range (803-Yes), in operation 805, the electronic device may detect a grip on the electronic device independently of the first capacitance stored in memory. For example, the electronic device may detect a grip on the electronic device independently of the first capacitance stored in memory and/or a register (e.g., the register in the controller 312 of FIG. 3), based on whether the voltage outputted from the grip sensor maintains the preset voltage by the second capacitance within the range. For example, the electronic device may identify a grip on the electronic device when the voltage of the preset node is identified to be greater than the preset voltage. For example, the electronic device may detect release of a grip on the electronic device when the voltage of the preset node is identified as matching the preset voltage.

In case that the voltage outputted from the grip sensor does not maintain the preset voltage by the second capacitance within the range (803-No), in operation 807, according to an embodiment of the disclosure, the electronic device may detect a grip on the electronic device using the first capacitance stored in the memory and the voltage outputted from the grip sensor. For example, the electronic device may adjust the capacitance of the capacitor based on occurrence of a preset event. The electronic device may detect a grip on the electronic device, based on the first capacitance and the voltage outputted from the grip sensor, while the capacitance of the capacitor is adjusted based on the occurrence of the event. The event may include the event exemplified in FIG. 2. For example, the event may include establishing a connection with an external object by a port of the electronic device. For example, the event may include booting at least one processor of the electronic device. For example, the event may include identifying an external object, including a hall sensor, in contact with the electronic device by the electronic device.

To meet specific absorption rate (SAR) standard, the electronic device may adjust intensity of a wireless signal radiated from the electronic device, based on detection of a grip on the electronic device. The electronic device may require a method for identifying a grip on the electronic device, in response to a reset of the grip sensor.

According to an embodiment of the disclosure, as described above, an electronic device (e.g., the electronic device 101 of FIG. 3) may comprise a grip sensor (e.g., the grip sensor 310 of FIG. 3), memory (e.g., the memory 130 of FIG. 3) for storing instructions, and at least one processor (e.g., the processor 120 of FIG. 3) operably coupled to the grip sensor and the memory. The at least one processor, when the instructions are executed, may adjust a capacitance of a capacitor (e.g., the first capacitor 314 of FIG. 4) in the grip sensor to change a voltage outputted from the grip sensor, based on a first capacitance stored in the memory. The at least one processor, when the instructions are executed, may detect a grip on the electronic device using the voltage changed by the capacitor after the capacitance of the capacitor is adjusted to a second capacitance greater than the first capacitance. The at least one processor, when the instructions are executed, may change the first capacitance stored in the memory to a third capacitance based on identifying that the capacitance of the capacitor is decreased to the third capacitance smaller than the first capacitance. The at least one processor, when the instructions are executed, may change the first capacitance stored in the memory to the second capacitance based on a number of the capacitance of the capacitor adjusted smaller than the second capacitance.

According to an embodiment of the disclosure, an electronic device may detect a grip on the electronic device by detecting a grip on the electronic device based on a capacitance stored in memory and a voltage outputted from a grip sensor.

For example, the at least one processor, when the instructions are executed, may detect the grip based on the first capacitance stored in the memory, and the voltage outputted from the grip sensor in response to occurrence of a preset event that the capacitance of the capacitor adjusted to the second capacitance.

For example, the at least one processor, when the instructions are executed, may detect the grip based on identifying the voltage greater than a preset voltage. The at least one processor, when the instructions are executed, may detect release of the grip based on identifying that the voltage is decreased to the preset voltage within a state in which the grip is detected.

For example, the preset event may occur based on at least one of an establishment of a connection by a port (e.g., the port 220 of FIG. 2) of the electronic device, booting of the electronic device, or identification of an external object (e.g., the external object 240 of FIG. 2) being contacted on the electronic device.

For example, the at least one processor, when the instructions are executed, may maintain one of the first capacitance or the third capacitance based on that the establishment of the connection by the port of the electronic device is disconnected.

For example, the electronic device may further comprise a temperature sensor (e.g., the temperature sensor 320 of FIG. 3) to measure a temperature of the grip sensor.

For example, the at least one processor, when the instructions are executed, may identify a temperature of the grip sensor from the temperature sensor. The at least one processor, when the instructions are executed, may identify the first capacitance based on a parameter corresponding to the identified temperature among parameters mapped to different temperatures which are stored in the memory.

For example, the at least one processor, when the instructions are executed, may change a parameter, corresponding to the identified temperature among the parameters, based on the third capacitance, based on identifying that the capacitance of the capacitor is decreased to the third capacitance.

For example, the grip sensor may include an amplifier (e.g., the amplifier 420 of FIG. 4) including a noninverted input (e.g., the noninverted input 420-2 of FIG. 4) that is grounded, an inverted input (e.g., the inverted input 420-1 of FIG. 4) connected to an end (e.g., the end 401-1 of the first capacitor 314 of FIG. 4) of the capacitor which is a first capacitor, and an output node (e.g., the output node 420-3 of FIG. 4) connected to the preset node. The grip sensor may include a second capacitor (e.g., the second capacitor 403 of FIG. 4) including an end (e.g., the end 403-1 of the second capacitor 403 of FIG. 4) connected to the inverted input, and another end (e.g., the end 403-2 of the second capacitor 403 of FIG. 4) connected to the preset node. The grip sensor may include a third capacitor (e.g., the fourth capacitor 407 of FIG. 4) including an end (e.g., the end 405-1 of the third capacitor 405 of FIG. 4) connected to the inverted input, and another end (e.g., the end 405-2 of the third capacitor 405 of FIG. 4) that is grounded. The grip sensor may include integrated circuitry (e.g., the integrated circuitry 411 of FIG. 4) including an end connected to the preset node, and another end connected to the at least one processor. The grip sensor may include a controller (e.g., the controller 312 of FIG. 3) to charge the first capacitor.

For example, the preset node may be a node to output the voltage to detect the grip on the electronic device, wherein the integrated circuitry may include a digital signal generator to output a digital value indicating the voltage.

For example, the at least one processor, when the instructions are executed, may detect the grip on the electronic device using the digital signal obtained through the digital signal generator.

According to an embodiment of the disclosure, as described above, an electronic device (e.g., the electronic device 101 of FIG. 3) may comprise a grip sensor (e.g., the grip sensor 310 of FIG. 3) including a capacitor (e.g., the capacitor 314 of FIG. 3) and a controller (e.g., the controller 312 of FIG. 3), and at least one processor (e.g., the processor 120 of FIG. 3) operably coupled to the grip sensor. The controller of the grip sensor may adjust a capacitance of the capacitor to change a voltage outputted form the grip sensor, based on a first capacitance stored in the controller. The controller may detect a grip on the electronic device using the voltage changed by the capacitor after the capacitance of the capacitor is adjusted to a second capacitance greater than the first capacitance. The controller may change the first capacitance stored in the controller to the third capacitance based on identifying that the capacitance of the capacitor is decreased to a third capacitance smaller than the first capacitance. The controller may change the first capacitance stored in the controller to the second capacitance based on a number of the capacitance of the capacitor adjusted smaller than the second capacitance.

For example, the controller may detect the grip based on the first capacitance stored in the controller and the voltage outputted from the grip sensor in response to occurrence of a preset event that the capacitance of the capacitor adjusted to the second capacitance.

For example, the controller may detect the grip based on identifying the voltage greater than a preset voltage. The controller may detect release of the grip based on identifying that the voltage is decreased to the preset voltage within a state in which the grip is detected.

For example, the preset event may occur based on at least one of establishing a connection by a port of the electronic device, booting of the electronic device, or the identification of an external object in contact with the electronic device.

For example, the controller may maintain one of the first capacitance or the third capacitance based on that the establishment of the connection by the port of the electronic device is disconnected.

For example, the electronic device may further comprise a temperature sensor to measure a temperature of the grip sensor.

For example, the controller may identify a temperature of the grip sensor from the temperature sensor. The controller may identify the first capacitance based on a parameter corresponding to the identified temperature among parameters mapped to different temperatures which are stored in the controller.

For example, the controller may change a parameter, corresponding to the identified temperature among the parameters, based on the third capacitance, based on identifying that the capacitance of the capacitor is decreased to the third capacitance.

According to an embodiment of the disclosure, as described above, a method of an electronic device (e.g., the electronic device 101 of FIG. 3) may comprise adjusting a capacitance of a capacitor in a grip sensor to change a voltage outputted from the grip sensor (e.g., the grip sensor 310 of FIG. 3), based on a first capacitance stored in memory (e.g., the memory 130 of FIG. 3). The method of the electronic device may comprise detecting a grip on the electronic device using the voltage changed by the capacitor after the capacitance of the capacitor is adjusted to a second capacitance greater than the first capacitance. The method of the electronic device may comprise changing the first capacitance stored in the memory to a third capacitance based on identifying that the capacitance of the capacitor is decreased to the third capacitance smaller than the first capacitance. The method of the electronic device may comprise changing the first capacitance stored in the memory to the second capacitance based on a number of the capacitance of the capacitor adjusted smaller than the second capacitance.

For example, the method of the electronic device may comprise detecting the grip based on the first capacitance stored in the memory, and the voltage outputted from the grip sensor, while the capacitance of the capacitor adjusted to the second capacitance is changed based on occurrence of a preset event.

For example, the method of the electronic device may comprise detecting the grip based on identifying the voltage greater than a preset voltage. The method of the electronic device may comprise detecting release of the grip based on identifying that the voltage is decreased to be lower than the preset voltage in a state detecting the grip.

For example, the method of the electronic device may comprise identifying a temperature of the grip sensor from a temperature sensor. The method of the electronic device may comprise identifying the first capacitance based on a parameter corresponding to the identified temperature among parameters mapped to different temperatures which are stored in the memory.

For example, the method of the electronic device may comprise changing a parameter, corresponding to the identified temperature among the parameters, based on the third capacitance, based on identifying that the capacitance of the capacitor is decreased to the third capacitance.

According to an embodiment of the disclosure, as described above, an electronic device (e.g., the electronic device 101 of FIG. 3) may comprise a grip sensor (e.g., the grip sensor 310 of FIG. 3), memory (e.g., the memory 130 of FIG. 3) for storing instructions, and at least one processor (e.g., the processor 120 of FIG. 3) operably coupled to the grip sensor and the memory. The at least one processor, when the instructions are executed, may adjust a capacitance of a capacitor in the grip sensor, in a range indicated by a first capacitance stored in the memory. The at least one processor, when the instructions are executed, based on whether a voltage outputted from the grip sensor maintains a preset voltage by a second capacitance in the range, may detect a grip on the electronic device independently from the first capacitance. The at least one processor, when the instructions are executed, while the capacitance of the capacitor is adjusted based on occurrence of a preset event, may detect a grip on the electronic device based on the first capacitance and the voltage.

For example, the preset event may occur based on at least one of establishing a connection by a port of the electronic device, booting of the electronic device, or the identification of an external object in contact with the electronic device.

For example, the electronic device may further comprise a temperature sensor (e.g., the temperature sensor 320 of FIG. 3) to measure a temperature of the grip sensor.

For example, the at least one processor, when the instructions are executed, may identify a temperature of the grip sensor from the temperature sensor, and identify the first capacitance based on a parameter corresponding to the identified temperature among parameters mapped to different temperatures which are stored in the memory.

According to an embodiment of the disclosure, as described above, an electronic device (e.g., the electronic device 101 of FIG. 3) may comprise a grip sensor (e.g., the grip sensor 310 of FIG. 3) including a capacitor (e.g., the capacitor 314 of FIG. 3) and a controller (e.g., the controller 312 of FIG. 3), and at least one processor (e.g., the processor 120 of FIG. 3) operably coupled to the grip sensor. The controller of the grip sensor may adjust a capacitance of a capacitor in the grip sensor, in a range indicated by a first capacitance stored in the controller. The controller may detect a grip on the electronic device independently from the first capacitance based on whether a voltage outputted from the grip sensor maintains a preset voltage by a second capacitance in the range. The controller may detect a grip on the electronic device based on the first capacitance and the voltage, while the capacitance of the capacitor is adjusted based on occurrence of a preset event.

For example, the preset event may occur based on at least one of an establishment of a connection by a port (e.g., the port 220 of FIG. 2) of the electronic device, booting of the electronic device, or identification of an external object (e.g., the external object 240 of FIG. 2) being contacted on the electronic device.

For example, the electronic device may further comprise a temperature sensor to measure a temperature of the grip sensor.

For example, the controller may identify a temperature of the grip sensor from the temperature sensor, and identify the first capacitance based on a parameter corresponding to the identified temperature among parameters mapped to different temperatures which are stored in the controller.

According to an embodiment of the disclosure, as described above, a method of an electronic device (e.g., the electronic device 101 of FIG. 3) may comprise adjusting a capacitance of a capacitor (e.g., the capacitor 314 of FIG. 3) in a grip sensor (e.g., the grip sensor 310 of FIG. 3), in a range (e.g., the range 750 indicated by the first capacitance of FIG. 7) indicated by a first capacitance stored in memory (e.g., the memory 130 of FIG. 3). The method of the electronic device may comprise, based on whether a voltage outputted from the grip sensor maintains a preset voltage by a second capacitance in the range, detecting a grip on the electronic device independently from the first capacitance. The method of the electronic device may comprise, while the capacitance of the capacitor is adjusted based on occurrence of a preset event, detecting a grip on the electronic device based on the first capacitance and the voltage.

The electronic device according to various embodiments may be one of various types of electronic devices. The electronic devices may include, for example, a portable communication device (e.g., a smartphone), a computer device, a portable multimedia device, a portable medical device, a camera, a wearable device, or a home appliance. According to an embodiment of the disclosure, the electronic devices are not limited to those described above.

It should be appreciated that various embodiments of the disclosure and the terms used therein are not intended to limit the technological features set forth herein to particular embodiments and include various changes, equivalents, or replacements for a corresponding embodiment. With regard to the description of the drawings, similar reference numerals may be used to refer to similar or related elements. As used herein, each of such phrases as “A or B,” “at least one of A and B,” “at least one of A or B,” “A, B, or C,” “at least one of A, B, and C,” and “at least one of A, B, or C,” may include any one of or all possible combinations of the items enumerated together in a corresponding one of the phrases. As used herein, such terms as “1st” and “2nd,” or “first” and “second” may be used to simply distinguish a corresponding component from another, and does not limit the components in other aspect (e.g., importance or order). It is to be understood that if an element (e.g., a first element) is referred to, with or without the term “operatively” or “communicatively”, as “coupled with,” or “connected with” another element (e.g., a second element), it means that the element may be coupled with the other element directly (e.g., wiredly), wirelessly, or via a third element.

As used in connection with various embodiments of the disclosure, the term “module” may include a unit implemented in hardware, software, or firmware, and may interchangeably be used with other terms, for example, “logic,” “logic block,” “part,” or “circuitry”. A module may be a single integral component, or a minimum unit or part thereof, adapted to perform one or more functions. For example, according to an embodiment of the disclosure, the module may be implemented in a form of an application-specific integrated circuit (ASIC).

Various embodiments as set forth herein may be implemented as software (e.g., the program 140) including one or more instructions that are stored in a storage medium (e.g., internal memory 136 or external memory 138) that is readable by a machine (e.g., the electronic device 101). For example, a processor (e.g., the processor 120) of the machine (e.g., the electronic device 101) may invoke at least one of the one or more instructions stored in the storage medium, and execute it, with or without using one or more other components under the control of the processor. This allows the machine to be operated to perform at least one function according to the at least one instruction invoked. The one or more instructions may include a code generated by a complier or a code executable by an interpreter. The machine-readable storage medium may be provided in the form of a non-transitory storage medium. Wherein, the term “non-transitory” simply means that the storage medium is a tangible device, and does not include a signal (e.g., an electromagnetic wave), but this term does not differentiate between a case in which data is semi-permanently stored in the storage medium and a case in which the data is temporarily stored in the storage medium.

According to an embodiment of the disclosure, a method according to various embodiments of the disclosure may be included and provided in a computer program product. The computer program product may be traded as a product between a seller and a buyer. The computer program product may be distributed in the form of a machine-readable storage medium (e.g., compact disc read only memory (CD-ROM)), or be distributed (e.g., downloaded or uploaded) online via an application store (e.g., PlayStore™), or between two user devices (e.g., smart phones) directly. If distributed online, at least part of the computer program product may be temporarily generated or at least temporarily stored in the machine-readable storage medium, such as memory of the manufacturer's server, a server of the application store, or a relay server.

According to various embodiments of the disclosure, each component (e.g., a module or a program) of the above-described components may include a single entity or multiple entities, and some of the multiple entities may be separately disposed in different components. According to various embodiments of the disclosure, one or more of the above-described components may be omitted, or one or more other components may be added. Alternatively or additionally, a plurality of components (e.g., modules or programs) may be integrated into a single component. In such a case, according to various embodiments of the disclosure, the integrated component may still perform one or more functions of each of the plurality of components in the same or similar manner as they are performed by a corresponding one of the plurality of components before the integration. According to various embodiments of the disclosure, operations performed by the module, the program, or another component may be carried out sequentially, in parallel, repeatedly, or heuristically, or one or more of the operations may be executed in a different order or omitted, or one or more other operations may be added.

It will be appreciated that various embodiments of the disclosure according to the claims and description in the specification can be realized in the form of hardware, software or a combination of hardware and software.

Any such software may be stored in non-transitory computer readable storage media. The non-transitory computer readable storage media store one or more computer programs (software modules), the one or more computer programs include computer-executable instructions that, when executed by one or more processors of an electronic device, cause the electronic device to perform a method of the disclosure.

Any such software may be stored in the form of volatile or non-volatile storage, such as, for example, a storage device like read only memory (ROM), whether erasable or rewritable or not, or in the form of memory, such as, for example, random access memory (RAM), memory chips, device or integrated circuits or on an optically or magnetically readable medium, such as, for example, a compact disk (CD), digital versatile disc (DVD), magnetic disk or magnetic tape or the like. It will be appreciated that the storage devices and storage media are various embodiments of non-transitory machine-readable storage that are suitable for storing a computer program or computer programs comprising instructions that, when executed, implement various embodiments of the disclosure. Accordingly, various embodiments provide a program comprising code for implementing apparatus or a method as claimed in any one of the claims of this specification and a non-transitory machine-readable storage storing such a program.

While the disclosure has been shown and described with reference to various embodiments thereof, it will be understood by those skilled in the art that various changes in form and details may be made therein without departing from the scope of the disclosure as defined by the appended claims and their equivalents.

No claim element is to be construed under the provisions of 35 U.S.C. § 112, sixth paragraph, unless the element is expressly recited using the phrase “means for” or “means.”

What is claimed is:

1. An electronic device comprising:
a grip sensor;
memory storing one or more computer programs; and
at least one processor communicatively coupled to the grip sensor and the memory,
wherein the one or more computer programs include computer-executable instructions that, when executed by the at least one processor individually or collectively, cause the electronic device to:
adjust a capacitance of a capacitor in the grip sensor to change a voltage outputted from the grip sensor, based on a first capacitance stored in the memory,
after the capacitance of the capacitor is adjusted to a second capacitance greater than the first capacitance, detect a grip on the electronic device using the voltage changed by the capacitor,
based on identifying that the capacitance of the capacitor is decreased to a third capacitance smaller than the first capacitance, change the first capacitance stored in the memory to the third capacitance, and
based on a number of the capacitance of the capacitor adjusted smaller than the second capacitance, change the first capacitance stored in the memory to the second capacitance.

2. The electronic device of claim 1, wherein the one or more computer programs include computer-executable instructions that, when executed by the one or more processors individually or collectively, cause the electronic device to:
in response to occurrence of a preset event that the capacitance of the capacitor adjusted to the second capacitance, detect the grip based on the first capacitance stored in the memory, and the voltage outputted from the grip sensor.

3. The electronic device of claim 2, wherein the one or more computer programs include computer-executable instructions that, when executed by the one or more processors, cause the electronic device to:
based on identifying the voltage greater than a preset voltage, detect the grip, and
in a state detecting the grip, detect a release of the grip based on identifying that the voltage is decreased to the preset voltage.

4. The electronic device of claim 3, wherein the preset event occurred based on at least one of an establishment of a connection by a port of the electronic device, booting of the electronic device, or identification of an external object being contacted on the electronic device.

5. The electronic device of claim 4, wherein the one or more computer programs include computer-executable instructions that, when executed by the one or more processors, cause the electronic device to:
based on that the establishment of a connection by the port of the electronic device is disconnected, maintain one of the first capacitance or the third capacitance.

6. The electronic device of claim 5, further comprising:
a temperature sensor to measure a temperature of the grip sensor.

7. The electronic device of claim 6, wherein the one or more computer programs include computer-executable instructions that, when executed by the one or more processors, cause the electronic device to:
identify a temperature of the grip sensor from the temperature sensor, and
identify the first capacitance based on a parameter corresponding to the identified temperature among parameters mapped to different temperatures which are stored in the memory.

8. The electronic device of claim 7, wherein the one or more computer programs include computer-executable instructions that, when executed by the one or more processors, cause the electronic device to:
based on identifying that the capacitance of the capacitor is decreased to the third capacitance, change a parameter, corresponding to the identified temperature among the parameters, based on the third capacitance.

9. The electronic device of claim 2, wherein the grip sensor include:
an amplifier including a noninverted input that is grounded, an inverted input connected to an end of the capacitor which is a first capacitor, and an output node connected to a preset node;
a second capacitor including an end connected to the inverted input, and another end connected to the preset node;
a third capacitor including an end connected to the inverted input, and another end that is grounded;
integrated circuitry including an end connected to the preset node, and another end connected to the one or more processors; and
a controller to charge the first capacitor.

10. The electronic device of claim 9,
wherein the preset node is a node to output the voltage to detect the grip on the electronic device, and
wherein the integrated circuitry include a digital signal generator to output a digital value indicating the voltage.

11. The electronic device of claim 10, wherein the one or more computer programs include computer-executable instructions that, when executed by the one or more processors, cause the electronic device to:
detect the grip on the electronic device using the digital signal obtained through the digital signal generator.

12. A method of operating an electronic device, the method comprising:
adjusting a capacitance of a capacitor in a grip sensor to change a voltage outputted from the grip sensor, based on a first capacitance stored in memory;
after the capacitance of the capacitor is adjusted to a second capacitance greater than the first capacitance, detecting a grip on the electronic device using the voltage changed by the capacitor;
based on identifying that the capacitance of the capacitor is decreased to a third capacitance smaller than the first capacitance, changing the first capacitance stored in the memory to the third capacitance; and
based on a number of the capacitance of the capacitor adjusted smaller than the second capacitance, changing the first capacitance stored in the memory to the second capacitance.

13. The method of claim 12, further comprising:
while the capacitance of the capacitor adjusted to the second capacitance is changed based on occurrence of a preset event, detecting the grip based on the first capacitance stored in the memory, and the voltage outputted from the grip sensor.

14. The method of claim 13, further comprising:
based on identifying the voltage greater than a preset voltage, detecting the grip; and
in a state detecting the grip, detecting a release of the grip based on identifying that the voltage is decreased to the preset voltage.

15. The method of claim 12, further comprising:
identifying a temperature of the grip sensor from a temperature sensor; and
identifying the first capacitance based on a parameter corresponding to the identified temperature among parameters mapped to different temperatures which are stored in the memory.

16. The method of claim 15, further comprising:
based on identifying that the capacitance of the capacitor is decreased to the third capacitance, changing a parameter, corresponding to the identified temperature among the parameters, based on the third capacitance.

17. An electronic device comprising:
a grip sensor;
memory storing one or more computer programs; and
one or more processors communicatively coupled to the grip sensor and the memory,
wherein the one or more computer programs include computer-executable instructions that, when executed by the one or more processors individually or collectively, cause the electronic device to:
adjust a capacitance of a capacitor in the grip sensor, in a range indicated by a first capacitance stored in the memory,
based on whether a voltage outputted from the grip sensor maintains a preset voltage by a second capacitance in the range, detect a grip on the electronic device independently from the first capacitance, and
while the capacitance of the capacitor is adjusted based on occurrence of a preset event, detect a grip on the electronic device based on the first capacitance and the voltage.

18. The electronic device of claim 17, wherein the preset event occurred based on at least one of an establishment of a connection by a port of the electronic device, booting of the electronic device, or identification of an external object being contacted on the electronic device.

19. The electronic device of claim 17, further comprises a temperature sensor to measure a temperature of the grip sensor.

20. The electronic device of claim 19, wherein the one or more computer programs further include computer-executable instructions that, when executed by the one or more processors individually or collectively, cause the electronic device to:
identify a temperature of the grip sensor from the temperature sensor, and
identify the first capacitance based on a parameter corresponding to the identified temperature among parameters mapped to different temperatures which are stored in the memory.
